(19) United States
(12) Patent Application Publication
(10) Pub. No.: US 2023/0387595 A1
(43) Pub. Date: Nov. 30, 2023

(54) COMMUNICATION DEVICE

(71) Applicant: ULTRAMEMORY INC., Tokyo (JP)

(72) Inventors: Kazuhiro YAMAGUCHI, Tokyo (JP); Takao ADACHI, Tokyo (JP)

(21) Appl. No.: 18/031,548

(22) PCT Filed: Oct. 23, 2020
(86) PCT No.: PCT/JP2020/039967

§ 371 Date: Apr. 12, 2023

(51) Int. Cl. H01Q 7/00

(52) U.S. Cl. CPC H01Q 7/00

(57) ABSTRACT

A communication device uses a magnetic field to enable communication between at least two coils, wherein the device comprises: a plate-shaped transmission coil; and a plate-shaped reception coil which is disposed so as to cross the in-plane direction with respect to the in-plane direction of the transmission coil.

### TECHNICAL FIELD

The present invention relates to a communication device.

### BACKGROUND ART

Volatile memories (RAMs) such as a dynamic random access memory (DRAM) have been known as storage devices. DRAM is required to enhance performance of an arithmetic unit (hereinafter referred to as a logic chip) and have a large capacity for suitably dealing with an increase in an amount of data. Under such circumstances, the memory (memory cell array, memory chip) has been miniaturized and increased in capacity by way of planar addition of cells. On the other hand, this type of increase in capacity is approaching its limit due to, for example, vulnerability to noise caused by the miniaturization and an increase in die area.

To address the foregoing, a technique has recently been developed in which a plurality of planar memories are three-dimensionally stacked to realize a large capacity. A semiconductor module for electrically connecting a plurality of stacked modules has also been proposed. Furthermore, a device has been proposed which enables communication between modules by means of coils (see, for example, see Patent Documents 1 and 2).

Patent Document 1: PCT International Publication No. WO2009/113373

Patent Document 2: PCT International Publication No. WO2008/102814

### DISCLOSURE OF THE INVENTION

### Problems to be Solved by the Invention

Patent Document 1 discloses that communication is enabled by making one side of a transmission coil and one side of a reception coil face each other. On the other hand, Patent Document 1 does not disclose any different arrangement of the transmission coil and the reception coil.

Patent Document 2 discloses that communication is enabled by combining one reception coil and a plurality of transmission coils. According to Patent Document 2, a transmitter is installed for each of the plurality of transmission coils, resulting in an increase in the coil arrangement area. Furthermore, according to Patent Document 2, chip costs increase due to the increase in the coil arrangement area.

In view of the foregoing, an object of the present invention is to provide a communication device in which a degree of freedom of arrangement is increased while suppressing an increase in chip cost.

### Means for Solving the Problems

The present invention relates to a communication device for enabling communication between at least two coils by using a magnetic field. The communication device includes a plate-shaped transmission coil; and a plate-shaped reception coil disposed such that an in-plane direction of the reception coil intersects with an in-plane direction of the transmission coil.

Preferably, the transmission coil and the reception coil are each a rectangular coil, and the reception coil is disposed such that one side of the reception coil is along one side of the transmission coil.

Preferably, the communication device further includes a support coil disposed such that one side of the support coil is along a direction in which one predetermined side of the transmission coil extends, and the support coil and the transmission coil are arranged side by side.

Preferably, the support coil partially overlaps with the transmission coil.

Preferably, the support coil includes a plurality of support coils that are disposed such that one side of each support coil is along one of directions of two sides of the transmission coil that intersect with each other.

Preferably, the communication device further includes a transmission circuit configured to output a transmission signal to the transmission coil that includes a plurality of transmission coils. It is preferable that the plurality of transmission coils are arranged in a direction along one side of the transmission coil, the reception coil is disposed such that the in-plane direction of the reception coil is along one side of the transmission coil that intersects with the direction in which the transmission coils are arranged, and the transmission circuit outputs the transmission signal in an identical direction to the plurality of transmission coils.

Preferably, the communication device further includes a switch unit configured to connect, from among the transmission coils, a plurality of predetermined transmission coils in series, and the transmission circuit transmits a transmission signal to the predetermined transmission coils connected by the switch unit.

Preferably, the transmission coils are arranged so as to overlap with each other, while sides of the transmission coils intersecting with the direction in which the transmission coils are arranged are out of alignment with each other between the transmission coils.

### Effects of the Invention

The present invention provides a communication device in which a degree of freedom of arrangement is increased, while suppressing an increase in chip cost.

### BRIEF DESCRIPTION OF THE DRAWINGS

FIG. 1 is a plan view illustrating Example 2 of a communication device according to a first embodiment of the present invention;

FIG. 2 is a plan view illustrating Example 3 of the communication device according to the first embodiment of the present invention;

FIG. 3 is a side view illustrating Example 3 of the communication device according to the first embodiment of the present invention;

FIG. 4 is a graph illustrating a relationship between time and a quantity of signals in Examples 2 and 3 of the communication device according to the first embodiment;

FIG. 5 is a plan view illustrating Example 4 of a communication device according to a second embodiment;

FIG. 6 is a plan view illustrating Example 5 of the communication device according to the second embodiment;

FIG. 7 is a plan view illustrating Example 6 of the communication device according to the second embodiment;

FIG. 8 is a graph illustrating a relationship between time and a quantity of signals in Examples 4 to 6 of the communication device according to the second embodiment;

FIG. 9 is a graph illustrating a ratio of a quantity of signals in Examples 4 to 6 of the communication device according to the second embodiment, with respect to a quantity of signals in a case where no support coil is used;

FIG. 10 is a plan view illustrating Example 7 of a communication device according to a third embodiment;

FIG. 11 is a side view illustrating Example 7 of the communication device according to the third embodiment;

FIG. 12 is a graph illustrating a relationship between time and a quantity of signals in Example 7 of the communication device according to the third embodiment;

FIG. 13 is a plan view illustrating examples of a communication device according to a fourth embodiment of the present invention;

FIG. 14 is a schematic diagram illustrating a way of connecting transmission coils in another example of the communication device according to the fourth embodiment;

FIG. 15 is a circuit diagram illustrating a way of operation of a switch unit in another example of the communication device according to the fourth embodiment;

FIG. 16 is a schematic diagram illustrating another way of connecting transmission coils in another example of the communication device according to the fourth embodiment;

FIG. 17 is a circuit diagram illustrating another way of operation of a switch unit in another example of the communication device according to fourth embodiment;

FIG. 18 is a graph illustrating a relationship between time and a current value of a transmission coil in other examples of the communication device according to the fourth embodiment;

FIG. 19 is a graph illustrating a relationship between time and a voltage value of a reception coil in other examples of the communication device according to the fourth embodiment; and

FIG. 20 is a schematic side view illustrating a positional relationship between two reception coils and two transmission coils of a communication device according to a modification.

### PREFERRED MODE FOR CARRYING OUT THE INVENTION

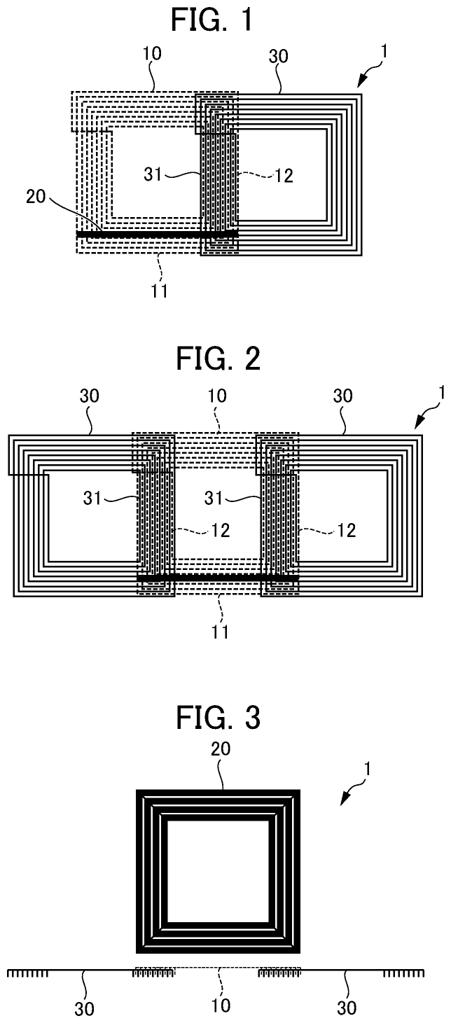

In the following, a communication device 1 according to each of embodiments of the present invention and a method for producing the communication device will be described with reference to FIGS. 1 to 19. The communication device 1 according to each embodiment is adapted to improve communication sensitivity of communication between a plate-shaped rectangular transmission coil 10 and a plate-shaped rectangular reception coil 20, while suppressing an increase in chip cost. The transmission coil 10 is disposed on, for example, one surface of one substrate (not shown). The reception coil 20 is disposed on, for example, on one surface of a different substrate (not shown). The different substrate is disposed such that an in-plane direction thereof is inclined with respect to an in-plane direction of the one substrate. The communication device 1 according to each embodiment is configured to enable communication between two substrates, for example.

### First Embodiment

Next, a communication device 1 according to a first embodiment of the present invention will be described with reference to FIGS. 1 to 4. The communication device 1 enables communication by using a magnetic field between at least two coils. For example, as illustrated in FIGS. 1 to 3, the communication device 1 includes a transmission coil 10, a reception coil 20, and a support coil(s) 30.

The transmission coil 10 is, for example, a plate-shaped coil. The transmission coil 10 is, for example, a rectangular coil. The transmission coil 10 is connected to, for example, a transmission circuit (not shown) that outputs a transmission signal.

The reception coil 20 is, for example, a plate-shaped coil. The reception coil 20 is, for example, a rectangular coil. The reception coil 20 is disposed such that an in-plane direction thereof intersects with an in-plane direction of the transmission coil 10. Specifically, as illustrated in FIG. 3, the reception coil 20 is disposed such that the in-plane direction thereof is orthogonal or substantially orthogonal to the in-plane direction of the transmission coil 10. Further, as illustrated in FIGS. 1 and 2, the reception coil 20 is disposed such that one side thereof is along one side (transmission-associated first side 11) of the transmission coil 10. In the present embodiment, the reception coil 20 is disposed such that one side thereof is along a winding of the one side (transmission-associated first side 11) of the transmission coil 10. The reception coil 20 is connected to, for example, a reception circuit (not shown) that receives a signal transmitted from the transmission coil 10.

The support coil 30 is, for example, a plate-shaped coil. The support coil 30 is, for example, a rectangular coil. The support coil 30 is a closed- or open-loop coil that is not connected to any of signal outputting circuits. The support coil 30 and the transmission coil 10 are arranged side by side. The support coil 30 is disposed such that an in-plane direction thereof is along the in-plane direction of the transmission coil 10. For example, the support coil 30 is disposed such that one side thereof is along a direction in which one predetermined side of the transmission coil 10 extends. Specifically, as illustrated in FIG. 1, the support coil 30 is disposed such that one side (support-associated first side 31) of the support coil 30 is along one side (transmission-associated second side 12) of the transmission coil 10 that intersects with the one side (transmission-associated first side 11) along which the reception coil 20 is disposed. In another example illustrated in FIG. 2, two support coils 30 are disposed such that one side (support-associated first side 31) of each support coil 30 is along an associated one of sides (transmission-associated second sides 12) of the transmission coil 10 that intersect with the one side (transmission-associated first side 11) along which the reception coil 20 is disposed. In other words, in the other example, the support coils 30 are arranged in pairs such that the one side (support-associated first side 31) is along an associated one of the two opposite sides (transmission-associated second sides 12) of the transmission coil 10. Thus, in the other example, the support coils 30 are arranged in pairs along the two sides (transmission-associated second sides 12) intersecting with the one side (transmission-associated first side 11) that overlaps with the reception coil 20.

In the present embodiment, the support coil 30 partially overlaps with the transmission coil 10. In the present embodiment, the support coil 30 overlaps also with the one side of the reception coil 20. As a result, as illustrated in FIG. 3, the support coil 30 is disposed in a region partially overlapping with the transmission coil 10, on one surface of one substrate. The support coil 30 is disposed adjacent to (in proximity to) an end of one side of the reception coil 20.

Next, an operation of the communication device 1 according to the present embodiment will be described. In response to application of a transmission signal to the transmission coil 10, a magnetic field is generated in the transmission coil 10. The reception coil 20 receives the signal by an induced electromotive force caused by the generated magnetic field.

Here, the induced electromotive force caused by the magnetic field generated in the transmission coil 10 causes a transient minute electric current to flow in the support coil 30. The support coil 30 generates, by the electric current, a magnetic field that reinforces the magnetic field outputted from the transmission coil 10. Thus, the reception coil 20 receives more signals by coupling with not only the magnetic field transmitted from the transmission coil 10, but also the magnetic field reinforced by the support coil 30.

### Examples

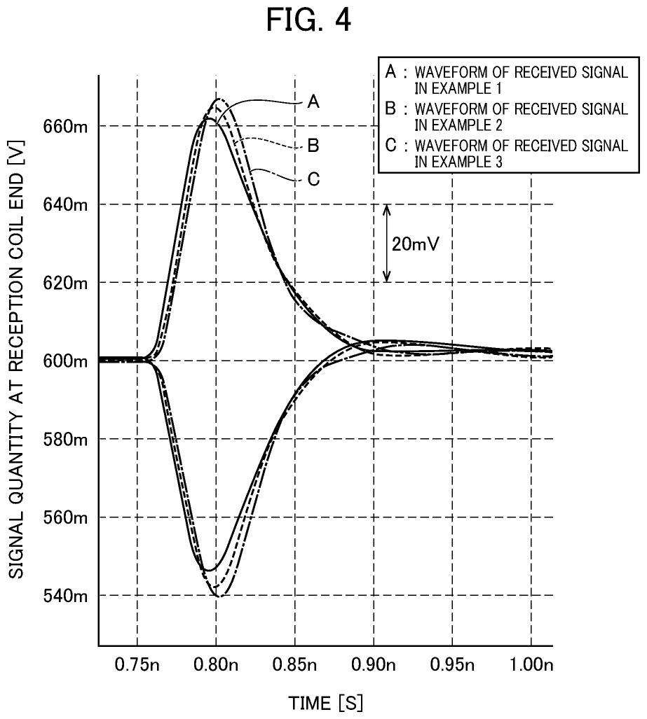

Next, examples of the communication device 1 according to the present embodiment will be described. Time and a change in a quantity of signals were measured in each of the following cases: the case where the support coil 30 was not used (hereinafter referred to as Example 1), the case where one support coil 30 was used (see FIG. 1; hereinafter referred to as Example 2), and the case where two support coils 30 were used (see FIG. 2; hereinafter referred to as Example 3). The results are illustrated in FIG. 4. As can be seen, an increase in the quantity of signals was observed in both Examples 2 and 3, in comparison with Example 1. In Example 2, it was confirmed that the quantity of signals increased by 6% relative to Example 1. In Example 3, it was confirmed that the quantity of signals increased by 10% relative to Example 1. Thus, both cases exhibited an increase in the quantity of signals.

The communication device 1 according to the first embodiment having the configuration described above provides the following advantages.
(1) The communication device 1 is for enabling communication between at least two coils by using a magnetic field, and includes the plate-shaped transmission coil 10 and the plate-shaped reception coil 20 that is disposed such that the in-plane direction of the reception coil 20 intersects with the in-plane direction of the transmission coil 10. This feature makes it possible to increase a degree of freedom of arrangement of the transmission coil 10 and the reception coil 20. Further, this feature allows for a free configuration using the pair of the transmission coil 10 and the reception coil 20, thereby suppressing an increase in chip cost.
(2) The transmission coil 10 and the reception coil 20 are each a rectangular coil, and the reception coil 20 is disposed such that one side of the reception coil 20 is along one side of the transmission coil 10. This feature can increase a degree of freedom of arrangement of the rectangular coils.
(3) The communication device 1 further includes the support coil 30 disposed such that one side of the support coil 30 is along a direction in which one predetermined side of the transmission coil 10 extends, and the support coil 30 and the transmission coil 10 are arranged side by side. This feature makes it possible for the communication device 1 to increase a quantity of signals to be received, by using the magnetic field reinforced by the support coil 30.
(4) The support coil 30 partially overlaps with the transmission coil 10. This feature makes it possible to increase the quantity of signals while suppressing an increase in the coil arrangement area.

### Second Embodiment

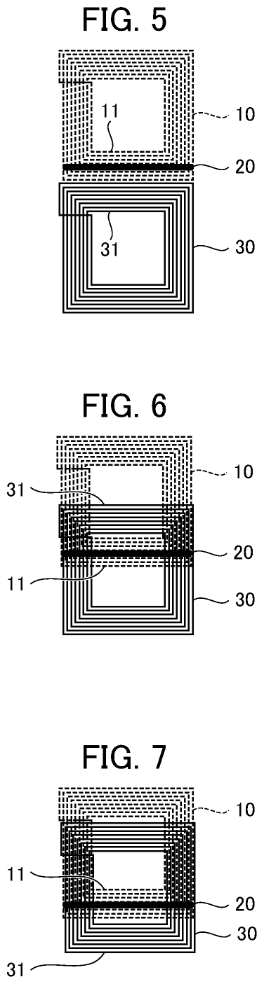

Next, a communication device 1 according to a second embodiment of the present invention will be described with reference to FIGS. 5 to 9. In the second embodiment, the same components as those described above are denoted by the same reference numerals, and the description thereof is simplified or omitted. The communication device 1 according to the second embodiment differs from the communication device 1 of the first embodiment in that, as illustrated in FIGS. 5 to 7, a support coil 30 is disposed adjacent to or overlaps with one side of a transmission coil 10 along which a reception coil 20 is disposed. Specifically, the communication device 1 according to the second embodiment has a configuration in which, in an in-plane direction of the transmission coil 10, the support coil 30 is disposed adjacent to or partially overlaps with one side (transmission-associated first side 11), and this constitutes the difference from the first embodiment.

### Examples

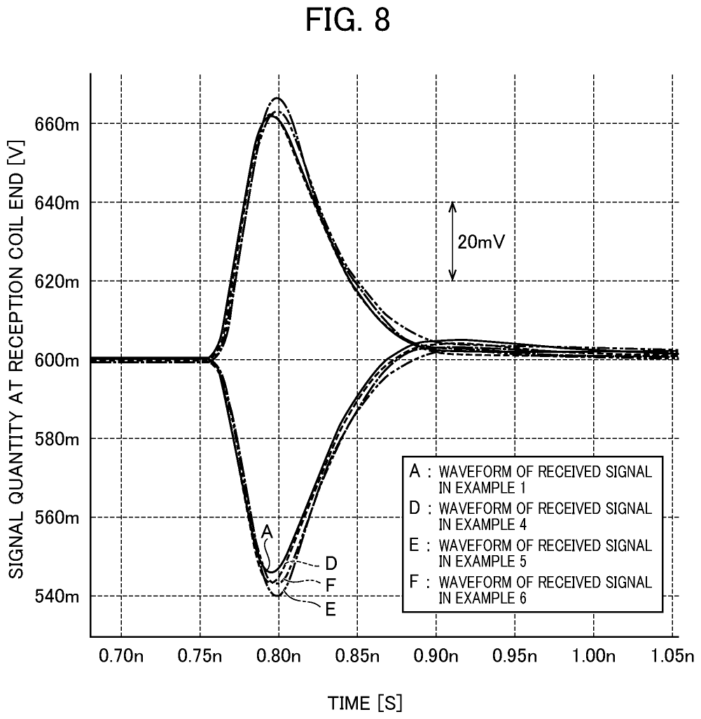

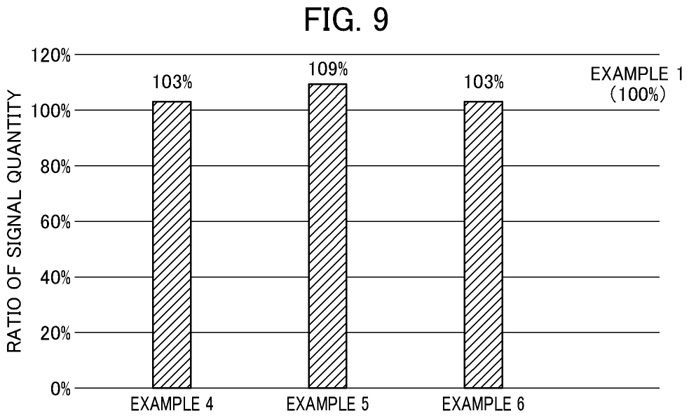

Next, examples of the communication device 1 according to the present embodiment will be described. Time and a change in a quantity of signals were measured in each of the following cases: the case where the support coil 30 was disposed adjacent to the transmission coil 10 (see FIG. 5; hereinafter referred to as Example 4), the case where the support coil 30 overlapped with the transmission coil 10 (see FIG. 6; hereinafter referred to as Example 5), and the case where the support coil 30 overlapped with the transmission coil 10 in a lager overlapping area (see FIG. 7; hereinafter referred to as Example 6). Further, the ratio of the quantity of signals in each example with respect to the quantity of signals in Example 1 was calculated. The results are illustrated in FIGS. 8 and 9. As can be seen, an increase in the quantity of signals was observed in all of Examples 4 to 6, in comparison with Example 1. In Example 4, it was confirmed that the quantity of signals increased by 3% relative to Example 1. In Example 5, it was confirmed that the quantity of signals increased by 9% relative to Example 1. In Example 6, it was confirmed that the quantity of signals increased by 3% relative to Example 1. Thus, all the cases exhibited an increase in the quantity of signals.

### Third Embodiment

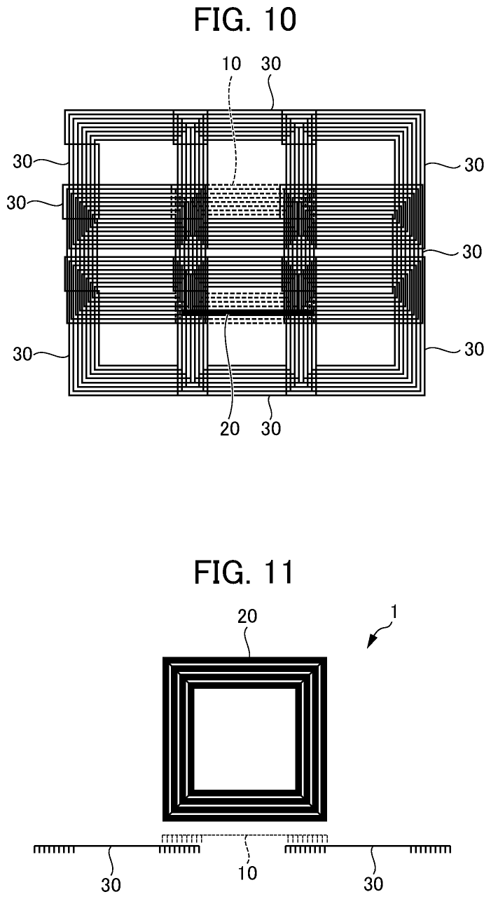

Next, a communication device 1 according to a third embodiment of the present invention will be described with reference to FIGS. 10 to 12. In the third embodiment, the same components as those described above are denoted by the same reference numerals, and the description thereof is simplified or omitted. The communication device 1 according to the third embodiment differs from the communication devices 1 of the first and second embodiments in that, as illustrated in FIGS. 10 and 11, a plurality of support coils 30 are disposed such that one side (support-associated first side 31) of each support coil 30 is along one of the directions of two sides (transmission-associated first and second sides 11 and 12) of the transmission coil 10 that intersect with each other. That is, the third embodiment has a configuration in which the plurality of support coils 30 are arranged along two directions in an in-plane direction of the transmission coil 10, and this constitutes the difference from the first and second embodiments. In particular, in the communication device 1 according to the third embodiment, the support coils 30 surround and enclose the transmission coil 10. Among the support coils 30, one support coil 30 disposed along one side (e.g., the transmission-associated first side 11) of the transmission coil 10 and another support coil 30 disposed along the other side (the transmission-associated second side 12) are at different positions in an out-of-plane direction.

### Examples

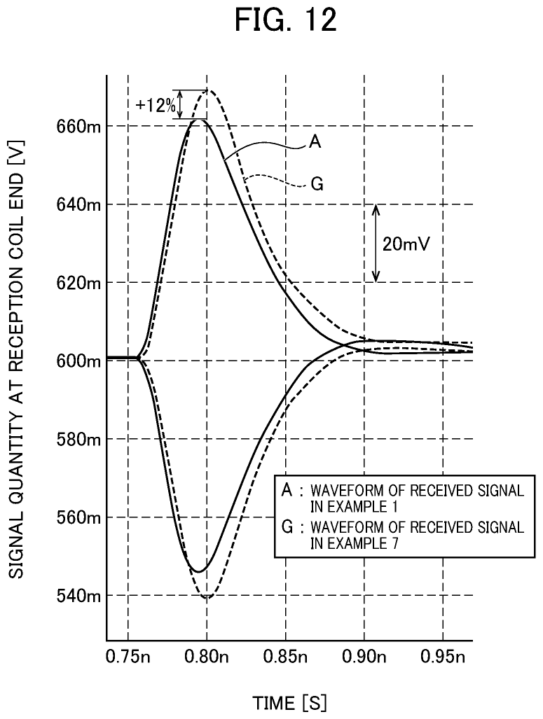

Next, an example of the communication device 1 according to the present embodiment will be described. Time and a change in a quantity of signals were measured in the case where the support coils 30 were adjacent to the transmission coil 10 (see FIGS. 10 and 11; hereinafter referred to as Example 7). The results are illustrated in FIG. 12. In Example 7, it was confirmed that the quantity of signals increased by 12% relative to Example 1.

The communication device 1 according to the third embodiment having the configuration described above provides the following advantages.
(5) The plurality of support coils 30 are disposed such that one side of each support coil 30 is along one of directions of two sides of the transmission coil 10 that intersect with each other. This feature makes it possible to increase a signal strength of a signal transmitted from the transmission coil 10.

### Fourth Embodiment

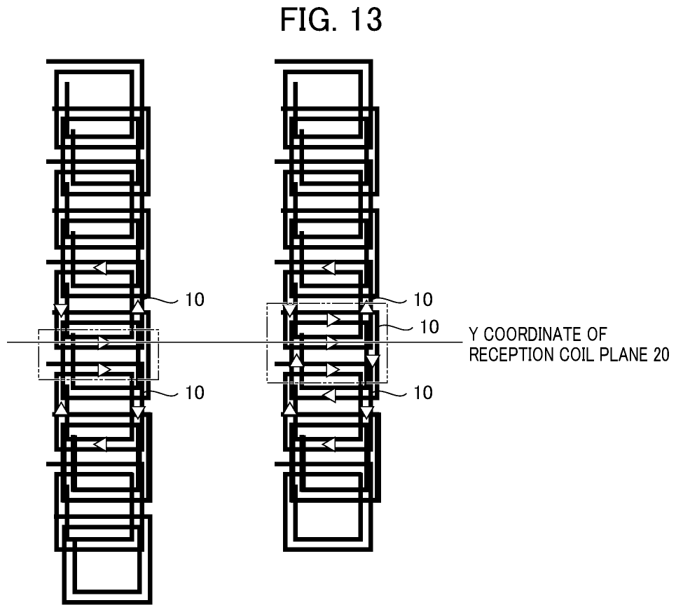

Next, a communication device 1 according to a fourth embodiment of the present invention will be described with reference to FIGS. 13 to 19. In the fourth embodiment, the same components as those described above are denoted by the same reference numerals, and the description thereof is simplified or omitted. As illustrated in FIG. 13, the communication device 1 according to the fourth embodiment improves flexibility in arrangement of the reception coil 20 by employing a plurality of transmission coils 10 to transmit signals to the reception coil 20. For example, one or more coils for transmitting a signal are selected from among the plurality of transmission coils 10 in accordance with the position of the reception coil 20, thereby contributing to improvement of the flexibility in arrangement of the reception coil 20.

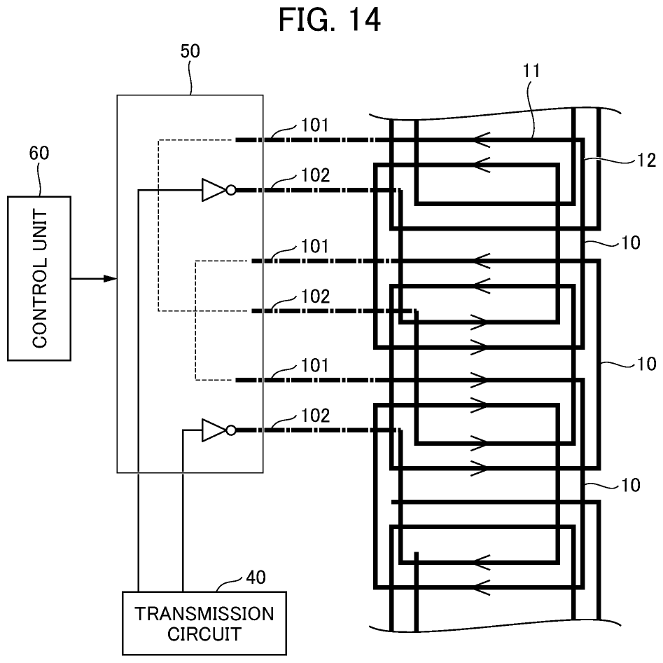

The communication device 1 according to the fourth embodiment differs from those of the first to third embodiments in that as illustrated in FIG. 13, the transmission coils 10 are arranged in the direction along one side (transmission-associated second side 12). Further, the communication device 1 according to the fourth embodiment differs from those of the first to third embodiments in that a reception coil 20 is disposed such that an in-plane direction thereof is along one side of the transmission coil 10 that intersects with the direction in which the transmission coils 10 are arranged. Furthermore, the communication device 1 according to the fourth embodiment differs from those of the first to third embodiments in that, as illustrated in FIGS. 14 to 17, the communication device 1 of the fourth embodiment includes a transmission circuit 40, a switch unit 50, and a control unit 60. In the present embodiment, the transmission coils 10 are arranged so as to overlap with each other, while the sides (transmission-associated first sides 11) intersecting with the direction in which the transmission coils 10 are arranged are out of alignment with each other.

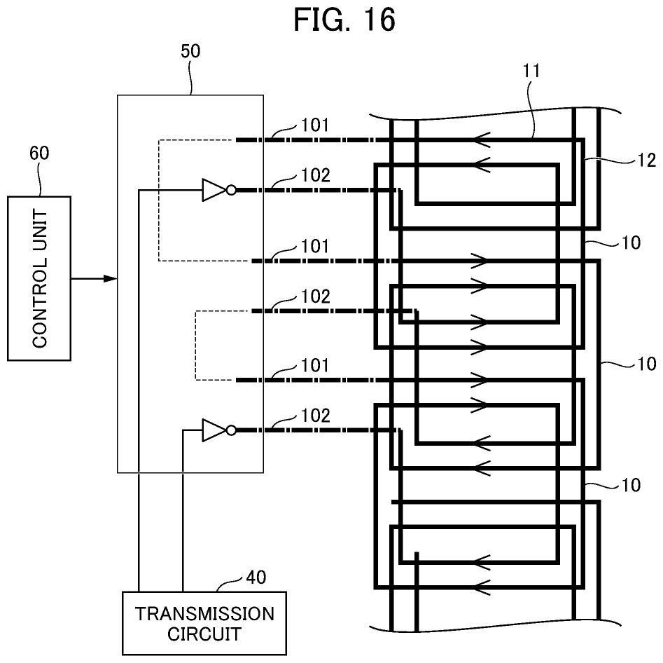

The transmission circuit 40 outputs a transmission signal to the plurality of transmission coils 10. For example, the transmission circuit 40 transmits a transmission signal by applying the signal across one end (hereinafter also referred to as a positive 101) of the transmission coil 10 and the other end (hereinafter also referred to as a negative 102) of the transmission coil 10. In the present embodiment, as illustrated in FIG. 14 and FIG. 16, the transmission circuit 40 applies a transmission signal across the negative 102 of one predetermined transmission coil 10 and the negative 102 of the next transmission coil 10 but one in the arrangement direction. The transmission circuit 40 outputs the transmission signal in the same direction to the plurality of transmission coils 10.

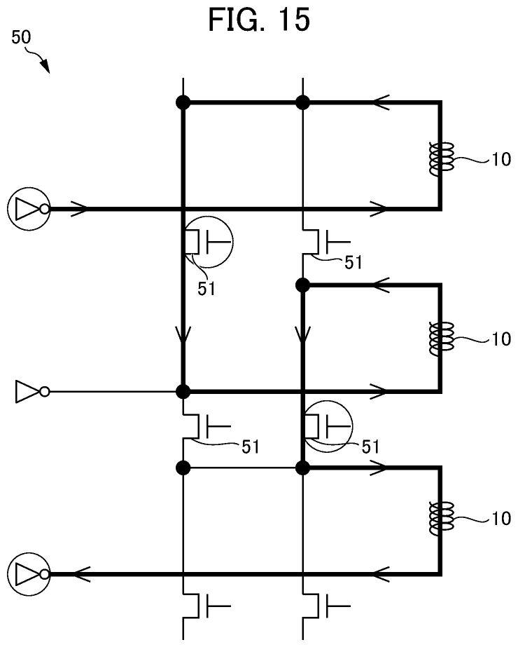

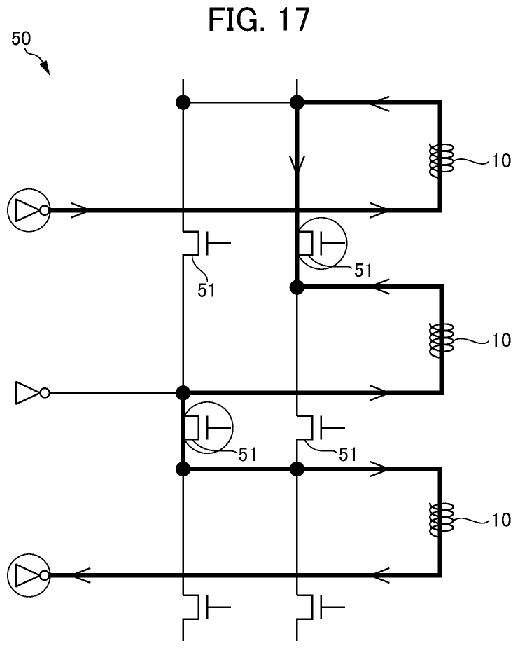

For example, as illustrated in FIGS. 15 and 17, the switch unit 50 connects a plurality of predetermined transmission coils 10 in series. The switch unit 50 selects the transmission coil 10 to be connected, according to the position of the reception coil 20, for example. As illustrated in FIGS. 15 and 17, the switch unit 50 connects two adjacent transmission coils 10 in series. The switch unit 50 connects two adjacent transmission coils 10 in series by, for example, activating or deactivating transfer gates 51 (hereinafter, also referred to simply as the gates 51). In the present embodiment, the switch unit 50 connects three adjacent transmission coils 10 in series. In FIGS. 15 and 17, the transfer gates 51 surrounded by a circle are active, while the transfer gates 51 not surrounded by a circle are inactive. Likewise, an inverter surrounded by a circle is active and connected to the transmission circuit 40, while the inverter not surrounded by a circle is inactive and its output is at high impedance.

According to the above-described configuration including the transmission circuit 40 and the switch section 50, the transmission circuit 40 applies a transmission signal across both ends of a set of the transmission coils 10 connected in series by the switch unit 50. As a result, a current corresponding to the signal flows in the same direction in the transmission coils 10 connected in series.

The control unit 60 is implemented by, for example, a CPU or a state machine in operation. The control unit 60 identifies the position of the reception coil 20 with respect to the transmission coils 10. The control unit 60 controls the operation of the switch unit 50 and the operation of the transmission circuit 40 in accordance with the identified position.

Next, the operation of the communication device 1 according to the present embodiment will be described. First, the reception coil 20 is disposed with respect to the transmission coils 10. Next, the transmission circuit 40 sequentially outputs a transmission signal to each of the transmission coils 10. The control unit 60 identifies, as the position of the reception coil 20, the position of one transmission coil 10 that outputs a transmission signal when the signal strength of a signal received by the reception coil 20 is maximized. The control unit 60 activates one gate 51 of the switch unit 50, in accordance with the position of the reception coil 20 corresponding to the identified position of the transmission coil 10.

The control unit 60 enables one or more transmission coils 10 located toward a side of the identified transmission coil 10 that is along an in-plane direction of the reception coil 20 and is closest to the reception coil 20 (this side is hereinafter referred to also as the communication edge). In the present embodiment, the control unit 60 enables three transmission coils 10. For example, as illustrated in FIG. 14, in the case where it is identified that the reception coil 20 is along the nth transmission coil 10 (n is a natural number) and is closest to the communication edge that is adjacent to the n−1th transmission coil 10, the control unit 60 controls the switch unit 50 so as to enable the n−1th and n−2th transmission coils 10. For example, as illustrated in FIG. 15, the control unit 60 connects the three transmission coils 10 in series by activating the gate 51 that connects the positive 101 of the nth transmission coil 10 to the positive 101 of the n−1th transmission coil 10 and by activating the gate 51 that connects the negative 102 of the n−1th transmission coil 10 to the positive 101 of the n−2th transmission coil 10.

Further, the control unit 60 connects the transmission circuit 40 to the negative 102 of the nth transmission coil 10 and the negative 102 of the n−2th transmission coil 10. As a result, as illustrated in FIG. 14, an electric current flows in the same direction in the transmission coils 10 connected in series at a location close to the reception coil 20.

On the other hand, for example, as illustrated in FIG. 16, in the case where it is identified that the reception coil 20 is along the nth transmission coil 10 and is closest to the communication edge that is adjacent to the n+1th transmission coil 10, the control unit 60 controls the switch unit 50 so as to enable the n+1th and n+2th transmission coils 10. For example, as illustrated in FIG. 17, the control unit 60 connects the three transmission coils 10 in series by activating the gate 51 that connects the positive 101 of the nth transmission coil 10 to the positive 101 of the n+1th transmission coil 10 and by activating the gate 51 that connects the negative 102 of the n+1th transmission coil 10 to the positive 101 of the n+2th transmission coil 10.

Further, the control unit 60 connects the transmission circuit 40 to the negative 102 of the nth transmission coil 10 and the negative 102 of the n+2th transmission coil 10. As a result, as illustrated in FIG. 16, an electric current flows in the same direction in the transmission coils 10 connected in series at a location close to the reception coil 20.

### Examples

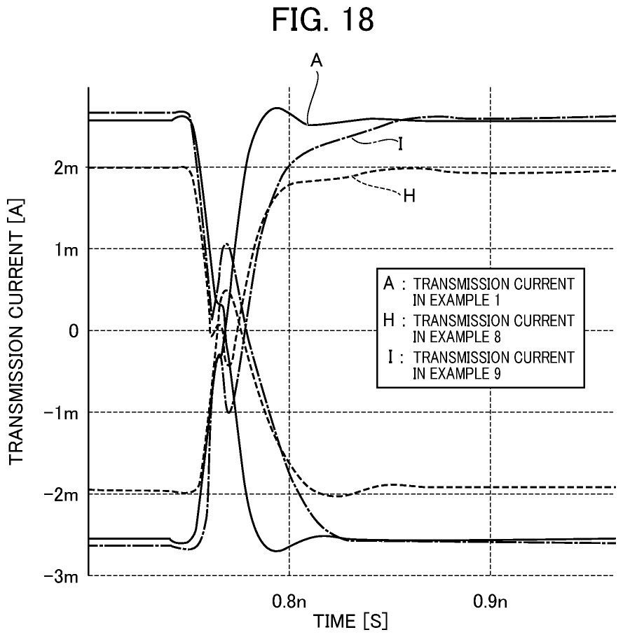

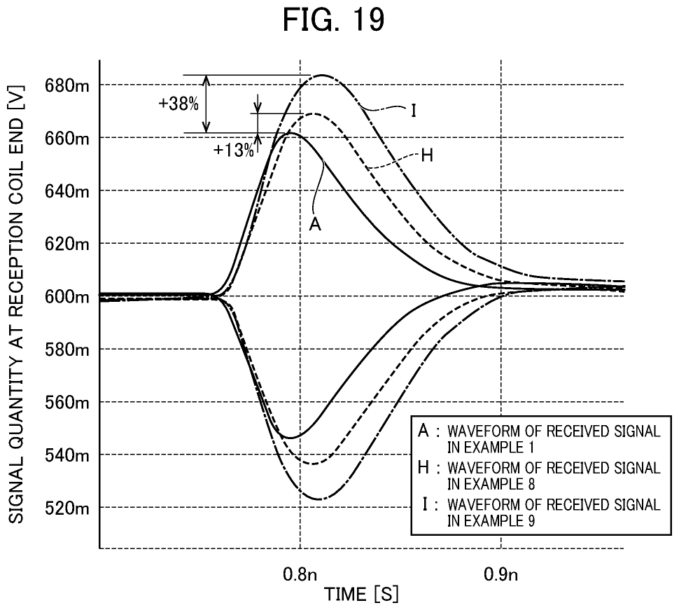

Next, examples of the communication device 1 according to the present embodiment will be described. As illustrated in FIG. 17, while the transmission coils 10 were connected in series, current waveforms in the transmission coils 10 and voltage waveforms in the reception coil 20 were compared respectively. The comparison was made between the following cases: the case where one transmission coil 10 and one reception coil 20 were arranged (Example 1), the case where three transmission coils 10 were connected in series (hereinafter referred to as Example 8), and the case where three transmission coils 10 were connected in series, and a current value was increased in accordance with an increase in a resistance value of the three transmission coils 10 so as to be made approximate to that in Example 1 (see FIG. 18; hereinafter referred to as Example 9). The results are illustrated in FIG. 19. As can be seen, it is confirmed that in the example 8, the reception voltage increased by 13% relative to Example 1. It is confirmed that in the example 9, the reception voltage increased by 38% relative to Example 1.

The communication device 1 according to the fourth embodiment having the configuration described above provides the following advantages.
(6) The communication device 1 further includes the transmission circuit 40 that outputs a transmission signal to the plurality of transmission coils 10. The transmission coils 10 are arranged in the direction along one side of the transmission coil 10, and the reception coil 20 is disposed such that the in-plane direction thereof is along one side of the transmission coil 10 that intersects with the direction in which the transmission coils 10 are arranged. The transmission circuit 40 outputs the transmission signal in the same direction to the plurality of transmission coils 10. Due to this feature, the plurality of transmission coils 10 can output the signal to the reception coil 20, making it possible to further increase the signal strength of the signal to be outputted.
(7) The communication device 1 further includes the switch unit 50 that connects, from among the transmission coils 10, a plurality of predetermined transmission coils 10 in series, and the transmission circuit 40 transmits a transmission signal to the plurality of predetermined transmission coils 10 connected by the switch unit 50. This feature makes it possible to output the transmission signal to the transmission coils 10 that are selected in accordance with the position of the reception coil 20. Thus, the transmission coils 10 to be enabled can be selected in accordance with the position of the reception coil 20, thereby contributing to improvement of the versatility of the design of the communication device 1. Further, the position of the reception coil 20 can be flexibly set with respect to the plurality of transmission coils 10, thereby making it possible to improve the yield in comparison with a case where the reception coil 20 is fixedly disposed along one transmission coil 10.
(8) The transmission coils 10 are arranged so as to overlap with each other, while the sides thereof intersecting with the direction in which the transmission coils 10 are arranged are out of alignment with each other between the transmission coils 10. As a result, the sides of the transmission coils 10 that intersect with the arrangement direction of the plurality of transmission coils 10 overlap with each other at a location overlapping with the reception coil 20. Thus, the signal strength of the transmission signal can be increased.

While preferred embodiments of the communication device of the present invention have been described above, the present invention is not limited to the embodiments described above, and appropriate modification may be made to the present invention.

For example, the first to third embodiments have been described as the case where the transmission coil 10 and the support coil 30 are disposed adjacent to or partially overlap with each other in the in-plane direction, but the present invention is not limited thereto. The transmission coil 10 and the support coil 30 may be disposed out of alignment in out-of-plane directions. The winding direction and the number of windings of the transmission coil 10 and those of the reception coil 20 are not particularly limited in the first to third embodiments. The winding direction and the number of windings of the support coil 30 are not particularly limited in the first to third embodiments.

In the first to third embodiments, one support coil 30 is disposed adjacent to one of the four sides of the transmission coil 10, but the present invention is not limited thereto. A plurality of support coils 30 may be disposed adjacent to or partially overlap with one side of the transmission coil 10. Specifically, a plurality of support coils 30 may be arranged in a direction intersecting with one side of the transmission coil 10, and one of the support coils 30 may be arranged adjacent to or partially overlap with the one side of the transmission coil 10. The cross-sectional size of the support coil 30 does not have to be the same as the cross-sectional size of the transmission coil 10.

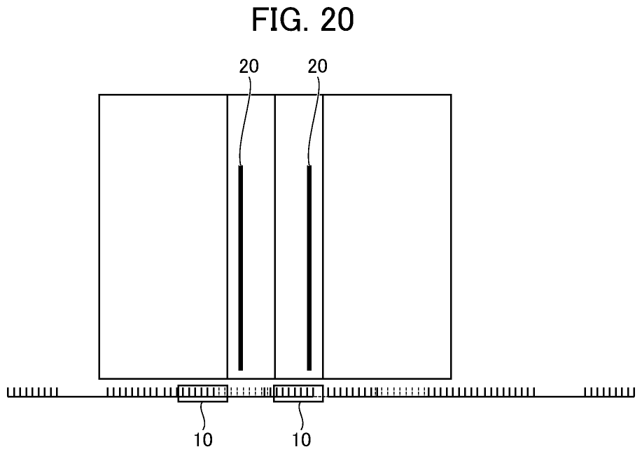

As illustrated in FIG. 20, in the fourth embodiment, two reception coils 20 may be arranged in the direction in which the series-connected transmission coils 10 are arranged. Here, the reception coils 20 may be arranged in an out-of-plane direction. This configuration makes it possible to transmit the same signal from a plurality of transmission coils 10 to a plurality of reception coils 20. Further, even in the case of using a plurality of reception coils 20, it is possible to ensure flexibility in arrangement of the reception coils 20 with respect to the transmission coils 10.

While the communication device 1 according to the fourth embodiment includes the control unit 60, the present invention is not limited thereto. The control unit 60 may not be included in the communication device 1, and may be used only at the time of manufacturing the communication device 1.

In the above embodiments, the transmission coil and the support coil do not have to be of the same size. The length of one side of the support coil may be shorter than the length of one side of the transmission coil. The support coil may have a rectangular shape whose short side is shorter than one side of the transmission coil. The support coil may be disposed such that either its short side or long side overlaps with the transmission coil.

### EXPLANATION OF REFERENCE NUMERALS

1: Communication device
10: Transmission coil
20: Reception coil
30: Support coil
40: Transmission circuit
50: Switch unit
60: Control unit

1. A communication device for enabling communication between at least two coils by using a magnetic field, the communication device comprising:
a plate-shaped transmission coil; and
a plate-shaped reception coil disposed such that an in-plane direction of the reception coil intersects with an in-plane direction of the transmission coil.

2. The communication device according to claim 1, wherein
the transmission coil and the reception coil are each a rectangular coil, and
the reception coil is disposed such that one side of the reception coil is along one side of the transmission coil.

3. The communication device according to claim 1, further comprising:
a support coil disposed such that one side of the support coil is along a direction in which one predetermined side of the transmission coil extends, wherein
the support coil and the transmission coil are arranged side by side.

4. The communication device according to claim 3, wherein
the support coil partially overlaps with the transmission coil.

5. The communication device according to claim 3, wherein
the support coil comprises a plurality of support coils that are disposed such that one side of each support coil is along one of directions of two sides of the transmission coil that intersect with each other.

6. The communication device according to claim 1, further comprising:
a transmission circuit configured to output a transmission signal to the transmission coil that comprises a plurality of transmission coils, wherein
the plurality of transmission coils are arranged in a direction along one side of the transmission coil,
the reception coil is disposed such that the in-plane direction of the reception coil is along one side of the transmission coil that intersects with the direction in which the transmission coils are arranged, and
the transmission circuit outputs the transmission signal in an identical direction to the plurality of transmission coils.

7. The communication device according to claim 6, further comprising:
a switch unit configured to connect, from among the transmission coils, a plurality of predetermined transmission coils in series, wherein
the transmission circuit transmits a transmission signal to the predetermined transmission coils connected by the switch unit.

8. The communication device according to claim 6, wherein
the transmission coils are arranged so as to overlap with each other, while sides of the transmission coils intersecting with the direction in which the transmission coils are arranged are out of alignment with each other between the transmission coils.
